(19) United States
(12) Patent Application Publication
(10) Pub. No.: US 2004/0089130 A1
(43) Pub. Date: May 13, 2004

(54) Computer interaction system of an electronic percussion music instrument

(76) Inventors: Yu-Chen Liu, Keelung (TW); Tzu-Chen Liu, Keelung (TW)

Correspondence Address: Yu-Chen Liu & Tzu-Chen Liu, P.O. Box No. 6-57, Chung-Ho, Taipei, 235, TW

(21) Appl. No.: 10/394,238

(22) Filed: Mar. 24, 2003

(30) Foreign Application Priority Data
Nov. 8, 2002 (TW) 091132983

(51) Int. Cl. G10H 7/00; G11C 5/00

(52) U.S. Cl. 84/602

(57) ABSTRACT

A computer interaction system of an electronic percussion music instrument mainly connects a set of electronic percussion music instruments with a computer preloaded with execution programs. After the computer reads audio-visual data saved in an audio-visual storage media via a multimedia play device and after the execution program verifies the audio-visual data in the audio-visual storage media as an original edition, the execution program commands a computer peripheral audio-visual device to generate relative sound and image thereby allowing a user to play the set of electronic percussion music instruments by following the correct beats. The system transmits the percussion signals back to the computer such that the execution program commands the computer to compare and record the beat or check if the sound quality is correct so as to achieve the objective of interactive teaching and game playing as well as the function of protecting the legalized copyright.

### BACKGROUND OF THE INVENTION

1) Field of The Invention

The present invention of a computer interaction system of an electronic music instrument is an interactive teaching and game playing system having a set of electronic percussion music instruments connecting with a computer and following the commands of a peripheral audio-visual device of the computer to allow a user to play the music instrument by following the correct beats.

2) Description of the Prior Art

Among the music instruments, percussion instruments are the easiest ones to learn. With some common music knowledge, a user can enjoy the striking. However, for a beginning learner, especially for whom learning to play a jazz or Latin drum, the most frequently encountered trouble is that he/she has to practice in a sound-insolated place in order to prevent making noise and bothering the others.

An electronic percussion music instrument (for example, an electronic drum) might be able to eliminate the noise problem by controlling the volume; however, lowering down the volume makes the user unable to feel the strong beat of the percussion music instrument What the most important thing is that, during the practice, the instructor can't feel whether tire learner's striking beat is strong enough thereby failing to provide the best advice and suggestion.

Furthermore, during practice, the learner playing a percussion music instrument usually listens to a part of music and practices according to the beats in the music. For example, a learner of a jazz drum might play a rock-and-roll music first; then pretending as the drummer in the band, the learner practices according to the drumming beats in the rock-and-roll music However, hearing both the practicing and the original drumming, the learner or the instructor is unable to tell the wrong beat or which beat needs to be strengthened. Of course, if they play the electronic drum, they can use headphones to overcome the problem of mixed sounds. Anyway, without an instructor, the learner usually has to spend a long time in practicing and groping in order to improve the techniques.

In view of the obstacles occurred when the learner practices playing the percussion music instrument, the inventor of the present invention designed a set of electronic music instruments connecting with a popularly used computer; with the instructions from a computer peripheral audio-visual device, a user is able to practice playing the music instrument by following the correct beat; therefore, according to the live music play recorded in the computer, the learner fully realizes whether the beat, sound quality or accent is correct thereby achieving the objective of using computer to teach interactively.

### SUMMARY OF THE INVENTION

Specifically, the present invention of a computer interaction system of an electronic percussion music instrument mainly connects a set of electronic music instruments with a computer preloaded with a set of execution program; after the computer reads audio-visual data saved in an audio-visual storage media via a multimedia play device, it orders a peripheral audio-visual device thereof to generate relative sound and image under the commands of the execution program thereby allowing a user to play the set of electronic percussion music instruments by following the correct beats; it also transmits the percussion signals back to the computer such that the execution program commands the computer to compare and record the beat or check if the sound quality is correct so as to achieve the objective of interactive teaching; that is the primary objective of the present invention.

Another objective of the present invention is that the execution program loaded in the computer includes an authentication mechanism for capturing and checking the serial number of an original audio-visual storage media; if the audio-visual data recorded in the audio-visual storage media has no serial number recorded legally, then the execution program doesn't generate relative sound or image toward the peripheral audio-visual device so as to safeguard the legal copyright and assist eliminating the pirated edition and rectifying the general mood of the society.

Yet another objective of the present invention is that the execution program loaded in the computer further includes a mechanism for setting up difficulty levels and player's choices as well as a memory operation mechanism for correcting errors and grading so as to achieve the effectiveness of playing game and entertaining in addition to allowing the user to learn how to play the music instrument.

To enable a further understanding of achieving the abovementioned objectives and effectiveness of the present invention, the brief description of the drawings is followed by the detailed description of a preferred embodiment.

### BRIEF DESCRIPTION OF THE DRAWINGS

FIG. 1 is a structural diagram of an entire system of the present invention.

FIG. 2 is a flowchart of an embodiment of an execution program of the present invention.

FIG. 3 is a flowchart of an embodiment of an authentication mechanism of the execution program of the present invention.

FIG. 4 is a flowchart of an embodiment of an option mechanism of the execution program of the present invention.

FIG. 5 is a flowchart of an embodiment of an error-correction mechanism of the execution program of the present invention.

### DETAILED DESCRIPTION OF THE PREFERRED EMBODIMENTS

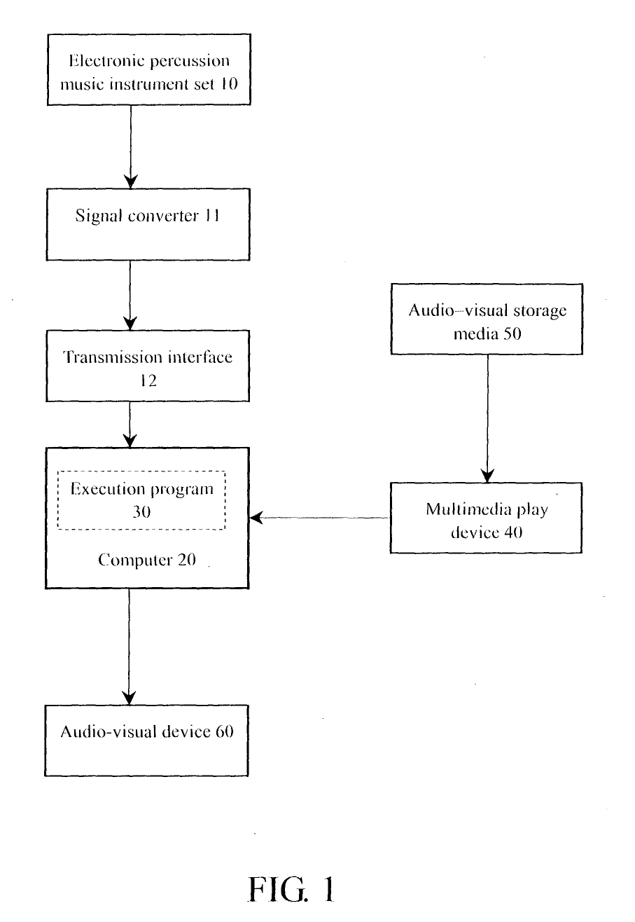

As indicated in FIG. 1, the present invention of a computer interaction system of an electronic music instrument mainly connects a set of electronic music instruments (10) with a computer (20) preloaded with a set of execution program (30); after the computer (20) reads audio-visual data saved in an audio-visual storage media (50) via a multimedia play device (40), it orders a peripheral audio-visual de vice (60) thereof to generate relative sound and image under the commands of the execution program (30) thereby allowing a user to play the set of electronic percussion music instruments (10) by following the correct beats; it also transmits the percussion signals back to the computer (20) such that the execution program (30) commands the computer (20) to compare and record the beat and the sound quality as well as to check if the accent is correct so as to achieve the objectives of interactive teaching and game playing.

The abovementioned electronic percussion music instrument set (10) connects with the computer (20) via a signal converter (11) and a transmission interface (12). A plurality of buzzing tabs (reeds) are disposed inside the electronic percussion music instrument set (10); striking makes the buzzing tabs generate vibration analog signal; that is of a prior art and will not be further described herefrom. When being stricken by the user, the electronic percussion music instrument set (10) generates and transmits different vibration analog signals to the signal converter (11) which converts the analog signals to digital signals and transmits them to the computer (20) through the transmission interface (12). The dimension of the transmission interface (12) is preferred to be one of the standard computer packages, such as USB, IEEE1394, IDE/ATAPI or SCSI.

The abovementioned computer (20) connects with the electronic percussion music instrument set (10) via the transmission interface (12) and also connects with the multimedia play device (40) and the peripheral audio-visual device (60); wherein the computer (20) includes at least a desktop personal computer (PC), a portable notebook PC, an industry PC, a personal digital assistant (PDA), an e-book and a pocket PC.

The multimedia play device (40) mainly reads the audio-visual data in various formats, such a MPEG1, MPEG2, WMA, MP3 and AAC, saved on the audio-visual storage media (50) including at least application devices such as a camcorder, a compact disc (CD) machine (for example, CD-RW, DVD-ROM, etc. ), a card reader (for example, PC Card Reader, CF Card Reader, SM Card Reader and MMC Card Reader), a DVD player, a VCD player, a CD player and a CD Discman.

The audio-visual storage media (50) includes at least a magnetic recording media (for example, a music cassette and a video cassette), an optical recording media (for example, CD-DA, CD-I, Photo-CD, Video-CD and DVD) capable of storing audio-visual data in various formats and tile recently developed silicon chip recording media (for example, CF Card, PC Card, SMC Card, MMC Card and MS Card); wherein, using the magnetic recording media to correspondingly fit with the multimedia play device (40), the signals have to be converted during music playing for the computer (20) to read.

The computer peripheral audio-visual device (60) includes at least a monitor and a speaker in any format.

The main function of the execution program (30) preloaded in the computer (20) is to command the peripheral audio-visual device (60) to generate relative sound and image after the computer (20) reads the audio-visual data preloaded on the audio-visual storage media (50) via the multimedia play device (40). In addition, when the user strikes the electronic percussion music instrument set (10), the signals transmitted back to the computer (20) makes the computer (20) compare and record the beats and sound quality via the execution program (30) thereby making the peripheral audio-visual device (60) generate relative sound and image. Through comparing the sounds and images respectively generated by the two different signal sources of the multimedia play device (40) and striking the electronic percussion music instrument set (10), the user is able to distinguish whether the beats, accents and sound quality generated by striking the electronic percussion music instrument set (10) match with that generated by the multimedia play device (40) such that the user judges it the playing is correct or not so as to achieve the objectives of using the computer (20) to teach interactively and play games.

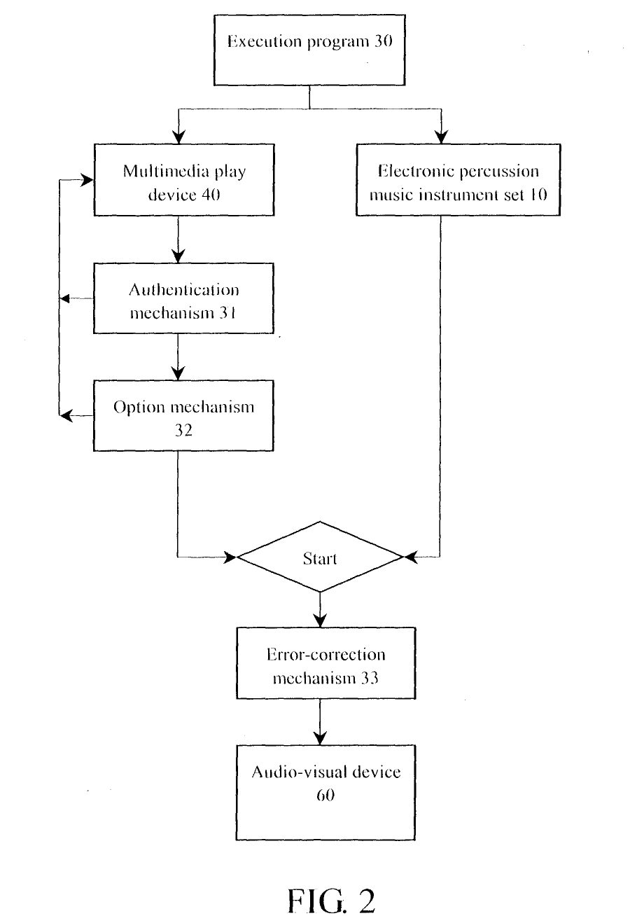

As indicated in FIG. 2, the execution program (30) of the present invention of a computer interaction system of an electronic percussion music instrument further includes an authentication mechanism (31), an option mechanism (32) and an error-correction mechanism (33). After the electronic percussion music instrument set (10) and the multimedia play device (40) respectively connect with the computer (20), the execution program (30) commands the signals generated by the multimedia play device (40) to sequentially pass the authentication mechanism (31) and the option mechanism (32) to enter a starting mode; the signals generated by the electronic percussion music instrument set (10) directly enters the starting mode. After being analyzed by the error-correction mechanism (33), both kinds of the signals make the audio-visual device (60) generate sounds and images so as to achieve the abovementioned efficiency.

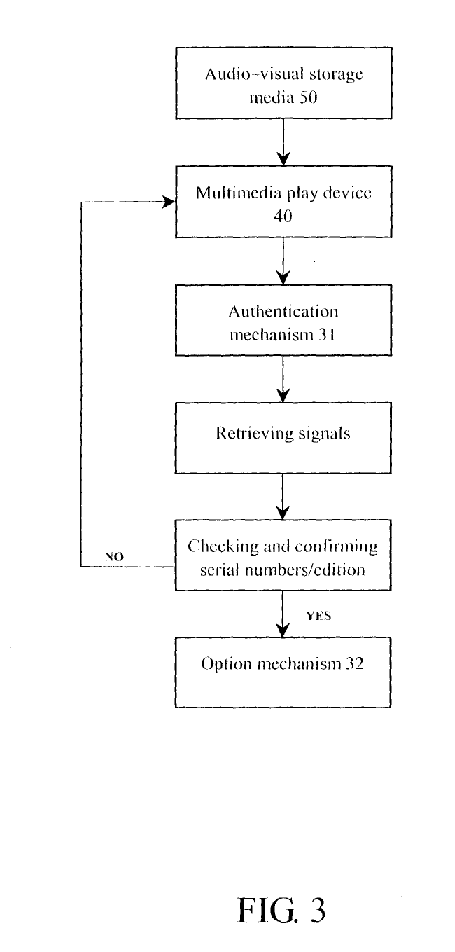

As indicated in FIG. 3, the authentication mechanism (31) retrieves, checks and confirms the serial number of the original audio-visual storage media (50). If the audio-visual storage media (50) is of the original edition, it allows signals generated by the multimedia play device (40) to enter into the option mechanism (32) of the next stage. If the audio-visual data recorded in the audio-visual storage media (50) has no legally recoded serial number, the next stage won't be executed and no relative sound or image will be generated toward the peripheral audio-visual device (60) so as to safeguard the legal copyright as well as assist eliminating the pirate edition and rectifying general mood of the society.

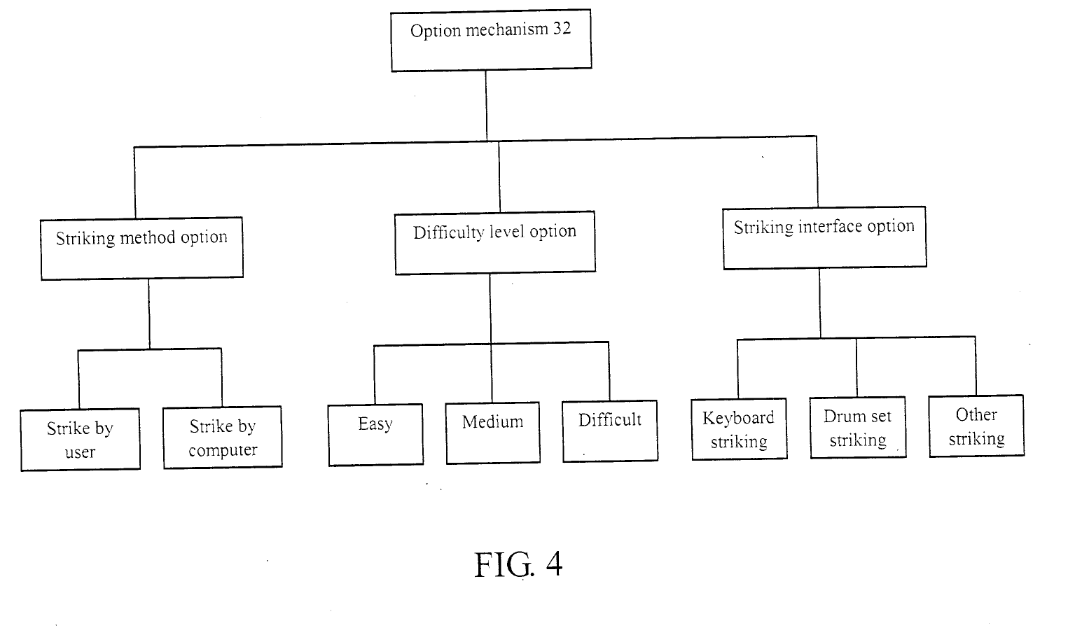

As indicated in FIG. 4, the option mechanism (32) further includes the striking method option, difficulty level option and striking interface option; wherein, the striking method option mainly provides the user options to strike by him/herself or through the computer (20). To strike through the computer (20), the execution program (30) commands the computer (20) to imitate the audio-visual data recorded in the audio-visual storage media (50) to make exemplary striking for the user. The difficulty level option includes three choices—easy, medium and difficult levels; it mainly provides a standard for the error-correction mechanism (33) at the next stage to compare with. The striking interface option includes a keyboard striking, a drum set striking, etc.; it mainly provides the user the options of learning or practice; wherein, the keyboard striking further has the effectiveness of playing games and entertaining.

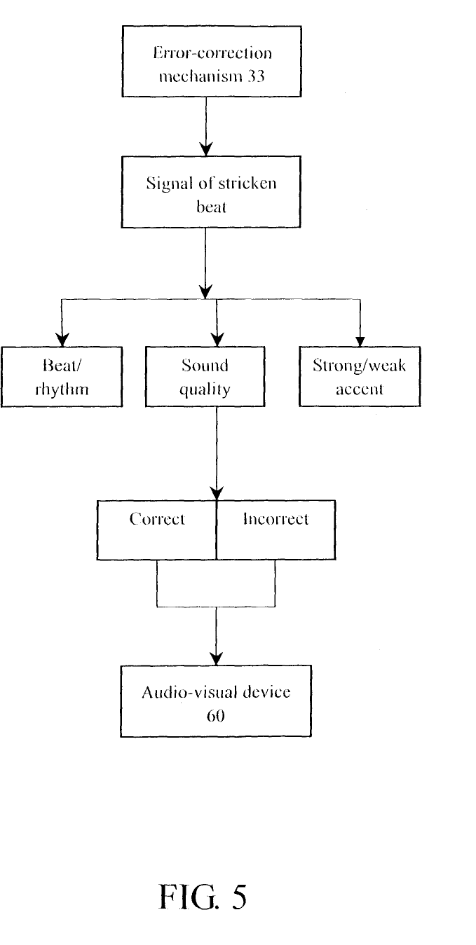

After choosing the setting for each item via the option mechanism (32), the user enters a starting mode. At this time, the signals generated by the multimedia play device (40) and the electronic percussion music instrument set (10) respectively enter the error-correction mechanism (33). If the option mechanism chooses the computer (20) to strike, then the computer (20) imitates the striking. As indicated in FIG. 5, when the electronic percussion music instrument set (10) is stricken, mainly based on the standard chosen for comparison, the error-correction mechanism (33) commands the computer (20) to calculate and compare the signals of the stricken beats, sound quality and accents with the audio-visual data recorded in the audio-visual storage media (50) to check if they match; it also records and counts the two kinds of signals to command the audio-visual device (60) to generate sound and image. Therefore, through recording the sound and image, the user is able to distinguish and improve the weakness of the striking so as to achieve the teaching objective of the present invention.

Furthermore, as mentioned above, the system of the present invention has both the functions of playing the game and entertaining In addition, during the implementation of the present invention, the execution program can be updated on the internet as the other prior art; that is an effect of a regular consuming execution program (a packaged software) and will not be described here.

It is of course to be understood that the embodiment described herein is merely illustrative of the principles of the invention and that a wide variety of modifications thereto may be effected by persons skilled in the art without departing from the spirit and scope of the invention as set forth in the following claims.

1. A computer interaction system of an electronic percussion music instrument connects a set of electronic percussion music instruments with a computer preloaded with a set of execution program; after the computer reads audio-visual data saved in an audio-visual storage media via a multimedia play device and after the execution program verifies the audio-visual data in the audio-visual storage media is of a original edition, the execution program commands a computer peripheral audio-visual device to generate relative sound and image thereby allowing a user to play the set of electronic percussion music instruments by following the correct beats; it also transmits the percussion signals back to the computer such that the execution program commands the computer to compare and record the beat or check if the sound quality is correct so as to achieve the objective of interactive teaching and game playing.

2. The computer interaction system of an electronic percussion music instrument according claim 1, wherein the electronic percussion music instrument set connects with the computer via a signal converter and a transmission interface; striking the electronic percussion music instrument set transmits the striking signals to the signal converter for converting into digital signals to be further transmitted to the computer via the transmission interface.

3. The computer interaction system of an electronic percussion music instrument according claim 1, wherein the dimensions of the transmission interface includes at least USB, IEEE1394, IDE/ATAPI or SCSI.

4. The computer interaction system of an electronic percussion music instrument according claim 1, wherein the execution program further includes an authentication mechanism, an option mechanism and an error-correction mechanism; the execution program commands the signals generated by the multimedia play device to sequentially pass the authentication mechanism and the IS *option mechanism to enter a starting mode; the signals generated by the electronic percussion music instrument set directly enters the starting node; after being analyzed by the error-correction mechanism, both kinds of the signals make the audio-visual device generate sounds and images.

5. The computer interaction system of an electronic percussion music instrument according claim 1, wherein the execution mechanism includes the authentication mechanism to retrieve, check and confirm the serial number of the original audio-visual storage media to command signal generated by the multimedia play device to enter the next stage.

6. The computer interaction system of an electronic percussion music instrument according claim 1, wherein the execution program includes the option mechanism which further includes a striking method option, a difficulty level option and a striking interface option.

7. The computer interaction system of an electronic percussion music instrument according claim 1, wherein the execution mechanism includes the error-correction mechanism; when the electronic percussion music instrument set is stricken, the error-correction mechanism commands the computer to calculate and compare the signals of the stricken beats, sound quality and accents with the audio-visual data recorded in the audio-visual storage media to check if they match; it also records and counts the two kinds of signals to command the audio-visual device to generate sound and image.

8. The computer interaction system of an electronic percussion music instrument according claim 1, wherein the computer includes at least a desktop personal computer (PC), a portable notebook PC, an industry PC, a personal digital assistant (PDA), an e-book and a pocket PC

9. The computer interaction system of an electronic percussion music instrument according claim 1, wherein the multimedia play device includes at least application devices such as a camcorder, a compact disc (CD) machine (for example, CD-RW, DVD-ROM, etc.), a card reader (for example, PC Card Reader, CF Card Reader, SM Card Reader and MMC Card Reader), a DVD player, a VCD player, a CD player and a CD Discman.

10. The computer interaction system of an electronic percussion music instrument according claim 1, wherein the audio-visual storage media includes at least a magnetic recording media, an optical recording media and a silicon chip recording media.

11. The computer interaction system of an electronic percussion music instrument according claim 1, wherein the audio-visual device includes at least a monitor and a speaker.
